(19) United States
(12) Patent Application Publication
(10) Pub. No.: US 2016/0300773 A1
(43) Pub. Date: Oct. 13, 2016

(54) PRINTED CIRCUIT BOARD, SEMICONDUCTOR PACKAGE AND METHOD OF MANUFACTURING THE SAME

(71) Applicant: Samsung Electro-Mechanics Co., Ltd., Suwon-si (KR)

(72) Inventors: Young Doo LEE, Suwon-si (KR); Dae Chul CHOI, Suwon-si (KR)

(73) Assignee: Samsung Electro-Mechanics Co., Ltd., Suwon-si (KR)

(21) Appl. No.: 15/061,219

(22) Filed: Mar. 4, 2016

(30) Foreign Application Priority Data
Apr. 13, 2015 (KR) 10-2015-0051554

(51) Int. Cl. H01L 23/31; H01L 25/065; H01L 23/00; H01L 25/00; H01L 21/56; H01L 23/498

(52) U.S. Cl. CPC H01L 23/3128; H01L 21/563; H01L 23/49811; H01L 23/49838; H01L 24/81; H01L 21/565; H01L 25/50; H01L 25/0655; H01L 2224/81192

(57) ABSTRACT

There is provided a printed circuit board includes a substrate having product areas for mounting elements and dummy areas disposed between two neighboring product areas, external connection terminals disposed on the product areas, and a plurality of dummy bumps disposed on the dummy areas.

### CROSS-REFERENCE TO RELATED APPLICATION

This application claims the benefit under 35 USC 119(a) of Korean Patent Application No. 10-2015-0051554 filed on Apr. 13, 2015, in the Korean Intellectual Property Office, the entire disclosure of which is incorporated herein by reference for all purposes.

### BACKGROUND

1. Field

The following description relates to a printed circuit board, a semiconductor package and a method of manufacturing the same.

2. Description of Related Art

To support the modern trend for multifunctionalization and speed increase of electronic products, heating elements are used in semiconductor chips, printed circuit boards and the like. For example, a heating element may be provided in a semiconductor chip or mounted on a printed circuit board to be connected to a main substrate. This trend is closely related to the trend for producing high-speed, high-density printed circuit boards. In line with the above-mentioned trends, there exists a demand for a significant improvement in the performance of high-density printed circuit boards, in addition to the demand to produce slimmer and lighter printed circuit boards having fine circuit wirings, high reliability, and the high-speed signal transfer structure.

In order to protect a chip mounted on the printed circuit board from an external environment, a process of sealing the chip using an epoxy molding compound (EMC) is generally performed. In the case of a flip-chip type module, an under-fill process may be undertaken, in which a filling material is disposed between the chip and the printed circuit board before a molding process is performed.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a printed circuit board includes a substrate having product areas for mounting elements, and dummy areas disposed between two neighboring product areas; external connection terminals disposed on the product areas; and a plurality of dummy bumps disposed on the dummy areas.

The plurality of dummy bumps on the dummy areas may be configured to impede a flow of a molding resin in the dummy areas during a molding process.

The dummy bumps and the external connection terminals may have substantially the same size and shape.

The dummy bumps may be formed to have a size greater than that of the external connection terminals.

The dummy bumps may be arranged on the dummy areas to be spaced apart from each other by a predetermined interval.

The dummy bumps may be arranged linearly.

The dummy bumps may be alternately arranged in a zigzag rows and columns of the dummy bumps.

In one general aspect, a semiconductor package includes a substrate having product areas for mounting elements and dummy areas present between two neighboring product areas, external connection terminals disposed on the product areas; a plurality of dummy bumps disposed on the dummy areas to maintain a constant velocity ratio of a flow of a molding resin, a semiconductor element mounted on the substrate through the external connection terminals, and a molding part including a resin material and covering the substrate and the semiconductor element.

The dummy bumps and the external connection terminals may have substantially the same size and shape.

A size of the dummy bumps may be greater than a size of the external connection terminals.

The dummy bumps may be arranged on the dummy areas and spaced apart from each other by a predetermined interval.

The dummy bumps may be arranged linearly.

The dummy bumps may be alternately arranged in a zigzag between rows and columns of the dummy bumps.

In another general aspect, a method of manufacturing a semiconductor package involves obtaining a substrate on which external connection terminals for mounting elements are disposed, and on which dummy bumps are disposed between the external connection terminals; mounting the elements on the external connection terminals without connecting to the dummy bumps; and covering the substrate with a molding resin.

The covering of the substrate may involve performing a mold underfill process by flowing the molding resin into spaces between the external connection terminals under the elements and between the dummy bumps.

The covering of the substrate may involve flowing the molding resin from one side of the substrate to another side of the substrate such that the molding resin flows into spaces between the external connection terminals under the elements.

Other features and aspects will be apparent from the following detailed description, the drawings, and the claims.

### BRIEF DESCRIPTION OF DRAWINGS

FIG. 1 is a plan view illustrating an example of a printed circuit board according to the present description.

FIG. 2 is a cross-sectional view of the example illustrated in FIG. 1.

FIG. 3 is a plan view illustrating another example of a printed circuit board.

FIG. 4 is a plan view illustrating another example of a printed circuit board.

FIG. 5 is a plan view illustrating an example of a semiconductor package.

FIG. 6 is a cross-sectional view of the example illustrated in FIG. 5.

FIG. 7 is a flow chart illustrating an example of a method of manufacturing a semiconductor package [LC1].

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. Like numerals refer to like elements throughout. As used herein, the term “and/or” includes any and all combinations of one or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the embodiments.

Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein is for describing embodiments only and is not intended to be limiting of the present description. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

Hereinafter, embodiments of the present description will be described with reference to schematic views illustrating various embodiments. In the drawings, for example, due to manufacturing techniques and/or tolerances, modifications of the shape shown may be estimated. Thus, embodiments should not be construed as being limited to the particular shapes of regions shown herein, for example, to include a change in shape results in manufacturing. The following embodiments may also be constituted by one or a combination thereof.

Printed Circuit Board

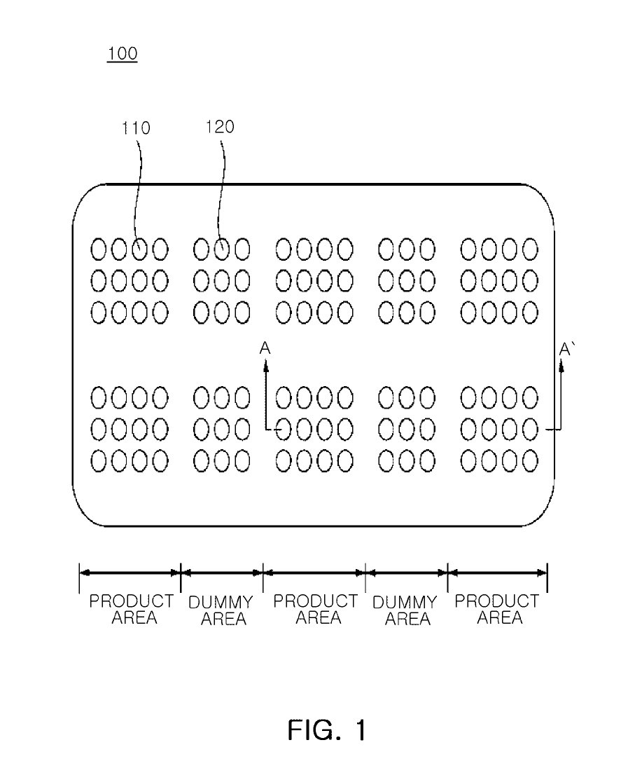

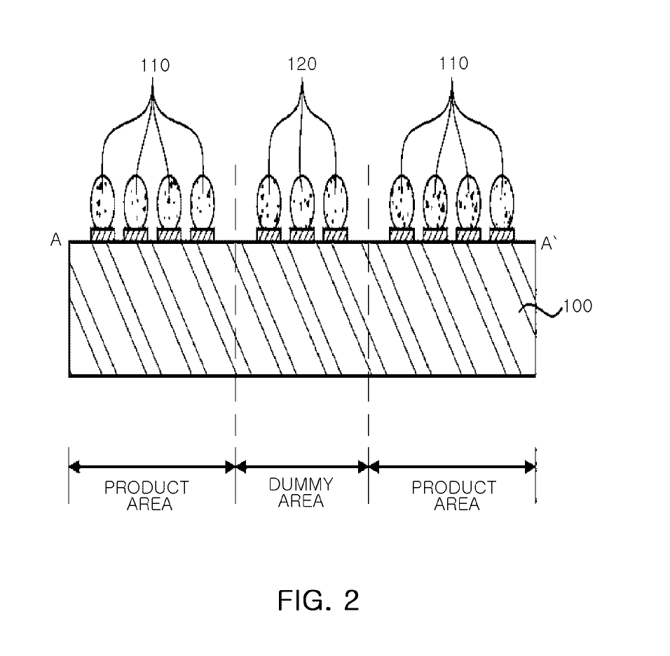

FIG. 1 is a plan view illustrating an example of a printed circuit board, and FIG. 2 is a cross-sectional view of the printed circuit board illustrated in FIG. 1.

Referring to FIGS. 1 and 2, a printed circuit board 100 includes product areas on which elements are mounted, and dummy areas present between respective product areas. External connection terminals 110 are formed on the product areas, and a plurality of dummy bumps 120 are formed on the dummy areas to maintain a constant velocity ratio of a flow of a molding resin.

The product areas of the printed circuit board 100 where the elements are mounted, may be provided with the external connection terminals 110 so that an electrical connection may be made the mounted elements.

The plurality of dummy bumps 120 are formed on the dummy area so as to be arranged linearly at a constant interval between two neighboring product areas so that the velocity ratio of the flow of the molding resin is constantly maintained. In this example, the dummy bumps 120 may be formed of the same material as that of the external connection terminals 110 and may have the same size as that of the external connection terminals 110. The dummy bumps 120 may be formed, for example, of a metal having good electricity conductivity such as gold, silver, copper, nickel, or the like. Unlike the external connection terminals 110, the dummy bumps 120 may not provide any electrical connection and may not connect to any element[LC2].

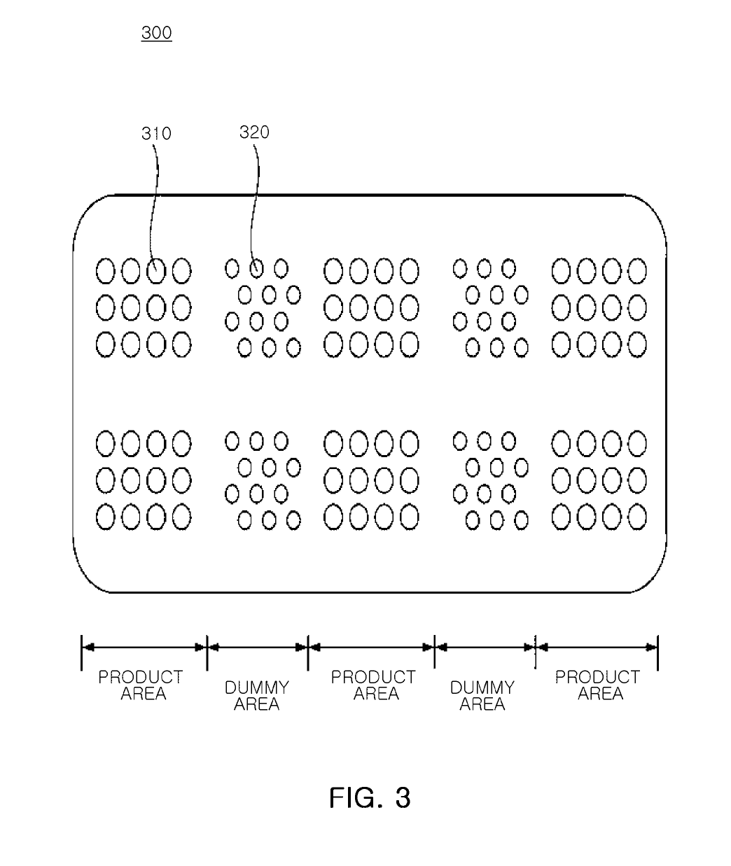

Further, FIG. 3 is a plan view illustrating another example of a printed circuit board according to the present description.

Referring to FIG. 3, a printed circuit board 300 includes product areas on which elements are mounted, and dummy areas present between respective product areas. A plurality of dummy bumps 320 are formed on the dummy area so as to be alternately arranged in a zigzag at a constant interval between the respective rows and columns between two neighboring product areas so that the velocity ratio of the flow of the molding resin is constantly maintained. In this example, the dummy bumps 320 are formed in the zigzag arrangement at a size smaller than that of external connection terminals 310 to adjust the flow of the molding resin. In this example, the dummy bumps 320 may be formed of the same material as that of the external connection terminals 310 and may be formed of a metal having good electricity conductivity such as gold, silver, copper, nickel, or the like.

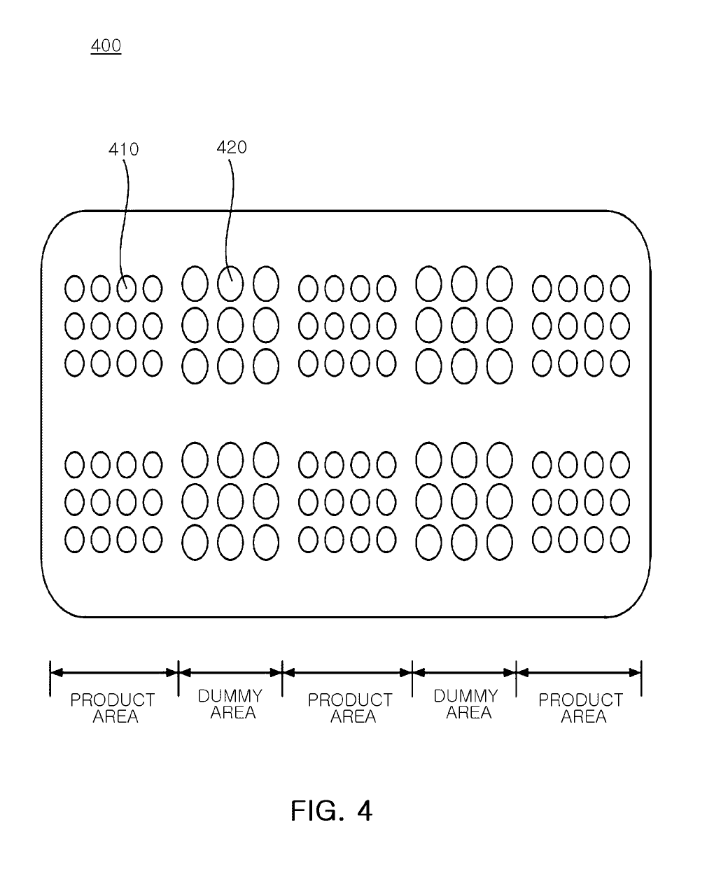

FIG. 4 is a plan view illustrating yet another example of a printed circuit board according to the present description.

Referring to FIG. 4, a printed circuit board 400 includes product areas on which elements are mounted, and dummy areas present between respective product areas. A plurality of dummy bumps 420 are formed on the dummy area and arranged at a constant interval on the dummy area between respective product areas so that the velocity ratio of the flow of the molding resin is constantly maintained. In this example, the dummy bumps 420 are formed to have a size greater than that of external connection terminals 410 to adjust the flow of the molding resin. In this example, the dummy bumps 420 may be formed of the same material as that of the external connection terminals 410 and may be formed of a metal having good electricity conductivity such as gold, silver, copper, nickel, or the like.

Meanwhile, FIGS. 2 and 3 [LC3]illustrate cases in which the dummy bumps have different sizes and arrangements, but are not limited thereto. For example, the dummy bumps may be formed in various sizes and arrangement patterns.

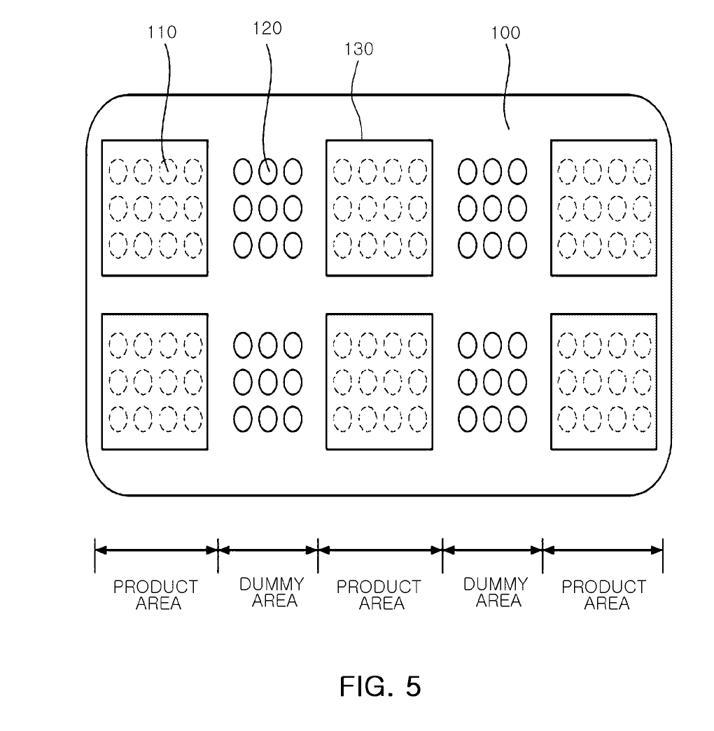

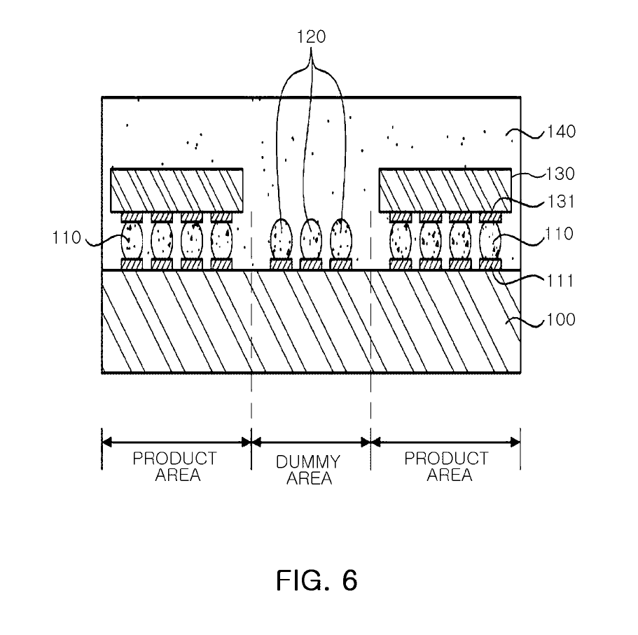

FIG. 5 is a plan view illustrating an example of a semiconductor package, and FIG. 6 is a cross-sectional view of the example of semiconductor package illustrated in FIG. 5.

Referring to FIG. 5, the semiconductor package includes a printed circuit board 100 having product areas on which elements are mounted, and dummy areas present between respective product areas. A plurality of external connection terminals 110 are formed on the product areas, and a plurality of dummy bumps 120 are formed on the dummy areas to maintain a constant velocity ratio of a flow of a molding resin. A semiconductor element 130 is mounted on the printed circuit board 100 through the external connection terminals 110, and a molding part 140 is formed over a top of the printed circuit board 100 on which the semiconductor element 130 is mounted, using a resin material, as illustrated in FIG. 6.

The printed circuit board (PCB) 100 is used to mount and electrically connect elements of an electronic device. The PCB 100 may be manufactured by etching a metal layer into a wiring pattern to form the necessary circuits. For example, the metal layer may be etched to remove a portion thereof while leaving only the circuits. The PCB 100 includes external connection terminals that may connect to electronic elements such as a semiconductor chip, and the like, in the outermost layer thereof.

Examples of the printed circuit board 100 may include a single sided PCB on which wirings are formed only on one surface of an insulating substrate, a double sided PCB on which the wirings are formed on both surfaces of the insulating substrate, and a multilayer board (MLB) on which the wirings are wired in a multilayer manner. Because a printed circuit board 100 known in the art is used, a detailed description of a configuration of the printed circuit board 100 will be omitted.

The external connection terminals 110 may be formed on the product areas of the printed circuit board 100 and may be electrically connected to the semiconductor chip. In this example, the external connection terminal 110 may serve to electrically connect the printed circuit board and the element to each other with solder bumps.

The plurality of dummy bumps 120 are formed on the dummy area and be arranged linearly at a constant interval between respective product areas so that the velocity ratio of the flow of the molding resin is constantly maintained. Here, the dummy bumps 120 may be formed of the same material as that of the external connection terminals 110 and may be formed of a metal having good electrical conductivity such as gold, silver, copper, nickel, or the like.

In this example, the dummy bumps 120 may be variously formed such as being formed to have the same size and arrangement as those of the external connection terminals 110, may be formed to have the size smaller than that of the external connection terminals 110 and in an arrangement of a zigzag pattern, and may be formed to have the size greater than that of the external connection terminals 110, and the like, thereby adjusting a velocity ratio of a flow of a molding resin.

Connection metal layers 111 and 131 may be respectively formed on the semiconductor chip 130 and the printed circuit board 100 so as to be connected to the external connection terminals 110. The connection metal layers 111 and 131 may be components physically and electrically connecting the semiconductor layer 130 and the external connection terminals 110 of the printed circuit board 100 to each other. The connection metal layers 111 and 131 may be formed, for example, of a metal having good electricity conductivity such as gold, silver, nickel, copper, or the like. According to one example, the connection metal layers 111 and 131 may be plated layers formed by plating.

The molding part 140 may seal a plurality of semiconductor chips 130. As a sealing material of the molding part, an epoxy molding compound (EMC) resin may be used, and outer portions of the semiconductor chips as well as spaces between the semiconductor chips 130 and the PCB 100 for molded underfill (MUF) may be sealed by an MUF process.

Method of Manufacturing Printed Circuit Board

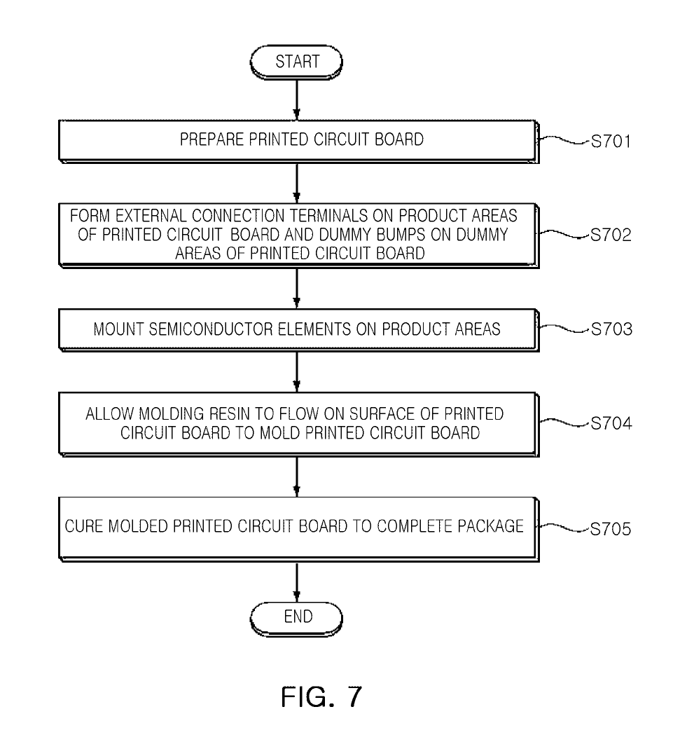

FIG. 7 is a flow chart illustrating an example of a method of manufacturing a semiconductor package.

Referring to FIG. 7, in S701, a printed circuit board is first prepared.

For example, a printed circuit board (PCB) 100 that is used to mount and wire elements of an electronic device, may be manufactured by etching a metal layer along a wiring pattern to configure necessary circuits (etching and removing the metal layer while leaving only the circuits on a line). The PCB 100 may include external connection terminals that may be connected to electronic elements such as a semiconductor chip, and the like, in the outermost layer thereof.

Examples of the printed circuit board 100 may include a single sided PCB on which wirings are only formed on one surface of an insulating substrate, a double sided PCB on which the wirings are formed on both surfaces of the insulating substrate, and a multilayer board (MLB) on which the wirings are wired in a multilayer structure. Because those skilled in the art would readily understand how to obtain the printed circuit board 100, a detailed description of a configuration of the printed circuit board 100 will be omitted.

Further, in S702, the external connection terminals are formed on product areas of the printed circuit board, and dummy bumps are formed on dummy areas thereof. The dummy bumps 120 may be formed by printing a solder paste by a printing process and performing a reflow process at the same time as the external connection terminals 110.

In this example, a plurality of dummy bumps 120 may be formed to be alternately arranged in a zigzag pattern with a constant interval between the respective rows and columns on the dummy area between respective product areas so that a velocity ratio of a flow of a molding resin is constantly maintained. For example, the dummy bumps 120 may be formed in the zigzag arrangement to have a size smaller than that of the external connection terminal 110 to adjust the flow of the molding resin. The dummy bump 120 may be formed of the same material as that of the external connection terminal 110. For example, the dummy bump 120 may be formed of a metal having good electricity conductivity such as gold, silver, copper, nickel, or the like.

Next, in S703, semiconductor elements are mounted on the product areas. A plurality of semiconductor chips 130 may be mounted on a chip mounting part in the product area of the printed circuit board 100. The above-mentioned semiconductor chips 130 may be mounted on the printed circuit board 100 in a flip-chip bonding scheme. That is, the semiconductor chips may be mounted on the chip mounting part of the printed circuit board 100 by a plurality of bumps having an array structure formed on bottoms of the semiconductor chips.

Next, in S704, a molding resin is allowed to flow on a surface of the printed circuit board to mold the printed circuit board.

For example, in the molding process, that is, the MUF process, the PCB for MUF on which the plurality of semiconductor chips are mounted may be disposed in a mold for molding the PCB, and a sealing resin may be injected into the mold for molding the PCB at a predetermined pressure through a gate (not illustrated) of the mold for molding the PCB. The injected sealing resin may seal the semiconductor chips in the mold while moving in a vertical direction (y direction) from a gate portion of the mold to a bent portion thereof.

Meanwhile, because a sufficient space is present in the dummy area between the semiconductor chip and the semiconductor chip, the sealing resin having fluidity may be easily moved. However, because a plurality of bumps are present in the product area between the semiconductor chip and the PCB for the MUF, the space in which the sealing resin is to be moved is very narrow. Thus, the sealing resin may not be easily moved in the product area. Thereby, the sealing resin may be filled in the space between the semiconductor chip and the PCB for the MUF later than the spaces between the semiconductor chips or on the semiconductor chips.

Thus, the dummy bumps may be formed on the dummy areas to allow the flow of the sealing resin of the dummy areas to be the same as that of the product areas between the semiconductor chips and the PCB for the MUF. Thereby, in an example of a PCB where a column of the semiconductor chips are installed, for a semiconductor chip farthest away from the gate portion of the mold, that is, the semiconductor chips adjacent to the bent portion of the mold, the sealing resin may arrive at a lower end portion of the molding for molding the PCB at the same flow velocity until the spaces between the semiconductor chips and the PCB for the MUF are filled.

As a result, the sealing resin may be equally filled in portions in which the sealing resin is not filled in the spaces between the semiconductor chips and the PCB for the MUF, thereby preventing an occurrence of voids.

Finally, in S705, the package may be completed by curing the molded printed circuit board.

As set forth above, according to an example of a method of manufacturing a printed circuit board, dummy bumps are disposed between external connection terminals, thereby ensuring that the sealing resin flow into all spaces between the external connection terminals under an element during a molding process. Accordingly, void defects may be prevented from occurring at an end of a strip substrate and a bump central portion of each element by forming the dummy bumps on a dummy area between mounting areas of elements to constantly maintain flow velocity of a molding resin in an under-fill molding process.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board comprising:
a substrate having product areas for mounting elements, and dummy areas disposed between two neighboring product areas;
external connection terminals disposed on the product areas; and
a plurality of dummy bumps disposed on the dummy areas.

2. The printed circuit board of claim 1, wherein the plurality of dummy bumps on the dummy areas are configured to impede a flow of a molding resin in the dummy areas during a molding process.

3. The printed circuit board of claim 1, wherein the dummy bumps and the external connection terminals have substantially the same size and shape.

4. The printed circuit board of claim 3, wherein the dummy bumps are formed to have a size greater than that of the external connection terminals.

5. The printed circuit board of claim 1, wherein the dummy bumps are arranged on the dummy areas to be spaced apart from each other by a predetermined interval.

6. The printed circuit board of claim 5, wherein the dummy bumps are arranged linearly.

7. The printed circuit board of claim 5, wherein the dummy bumps are alternately arranged in a zigzag between rows and columns of the dummy bumps.

8. A semiconductor package comprising:
a substrate having product areas for mounting elements, and dummy areas present between two neighboring product areas;
external connection terminals disposed on the product areas;
a plurality of dummy bumps disposed on the dummy areas to maintain a constant velocity ratio of a flow of a molding resin;
a semiconductor element mounted on the substrate through the external connection terminals; and
a molding part comprising a resin material and covering the substrate and the semiconductor element.

9. The semiconductor package of claim 8, wherein the dummy bumps and the external connection terminals have substantially the same size and shape.

10. The semiconductor package of claim 8, wherein a size of the dummy bumps is greater than a size of the external connection terminals.

11. The semiconductor package of claim 8, wherein the dummy bumps are arranged on the dummy areas and spaced apart from each other by a predetermined interval.

12. The semiconductor package of claim 11, wherein the dummy bumps are arranged linearly.

13. The semiconductor package of claim 11, wherein the dummy bumps are alternately arranged in a zigzag between rows and columns of the dummy bumps.

14. A method of manufacturing a semiconductor package, the method comprising:
obtaining a substrate on which external connection terminals for mounting elements are disposed, and on which dummy bumps are disposed between the external connection terminals;
mounting the elements on the external connection terminals; and
covering the substrate with a molding resin.

15. The method of claim 14, wherein the covering of the substrate comprises performing a mold underfill process by flowing the molding resin into spaces between the external connection terminals under the elements and between the dummy bumps.

16. The method of claim 14, wherein the covering of the substrate comprises flowing the molding resin from one side of the substrate to another side of the substrate such that the molding resin flows into spaces between the external connection terminals under the elements.
